(19) United States
(12) Patent Application Publication
(10) Pub. No.: US 2021/0287884 A1
(43) Pub. Date: Sep. 16, 2021

(54) SYSTEMS FOR WORKPIECE PROCESSING WITH PLASMA

(71) Applicant: NORDSON CORPORATION, Westlake, OH (US)

(72) Inventors: Thomas V. Bolden, Fremont, CA (US); James Harroun, Concord, CA (US); Bob Condrashoff, Concord, CA (US); John Guinn, San Carlos, CA (US)

(21) Appl. No.: 17/263,626

(22) PCT Filed: Jun. 10, 2019
(86) PCT No.: PCT/US2019/036328

§ 371 Date: Jan. 27, 2021

Related U.S. Application Data
(60) Provisional application No. 62/712,051, filed on Jul. 30, 2018.

(51) Int. Cl. H01J 37/32

(52) U.S. Cl. CPC H01J 37/32715; H01J 37/32633; H01J 37/32834

(57) ABSTRACT

Systems, methods, and apparatuses for workpiece processing with plasma, including thermal isolation of a workpiece holder assembly, are described. An apparatus includes a chamber that at least partially defines a processing space for generating plasma. The apparatus includes a base assembly that at least partially defines a lower end of the chamber and has an inner perimeter that defines an opening in the base assembly. The apparatus further includes a workpiece holder assembly positioned, at least in part, within the opening. The workpiece holder assembly includes heating element(s) and a body with an upper surface configured to receive a workpiece. A gap is defined between the inner perimeter of the base assembly and an outer perimeter of the body. The gap is configured to thermally isolate the base assembly from the body.

### CROSS REFERENCE TO RELATED APPLICATIONS

This application is a National Stage Application of International Patent Application No. PCT/US2019/036328, filed Jun. 10, 2019, which claims the benefit of U.S. Provisional Patent App. No. 62/712,051, filed Jul. 30, 2018, the entire disclosures of both of which are hereby incorporated by reference as if set forth in their entirety herein.

### TECHNICAL FIELD

This disclosure relates to systems for workpiece processing. More particularly, this disclosure relates to workpiece processing with plasma.

### BACKGROUND

Plasma processing systems are commonly used for modifying the surface properties of workpieces in various industrial applications. For example, plasma processing systems are routinely used to plasma treat the surfaces of integrated circuits, electronic packages, and printed circuit boards in semiconductor applications, solar panels, hydrogen fuel cell components, automotive components, and rectangular glass substrates used in flat panel displays.

Plasma treatment, however, presents a number of unique challenges. For example, heat generation remains a common problem, especially during those plasma treatments that require the workpiece to be held at high temperature during the treatment. Unchecked heat generation may produce a work environment in which operators are at risk of being burned unless the production facility undertakes expensive measures to address this risk, such as guards or barriers for the plasma treatment systems or devices. These safety measures also typically require additional floor space for each system or device. Excessive heat may also result in increased operational costs due to the additional energy needed to compensate for the energy lost as unwanted heat. These and other shortcomings are addressed in the present disclosure.

### SUMMARY

Disclosed herein are systems, methods, and apparatuses relating to various aspects of plasma treatment or processing. In an example apparatus relating to thermal isolation of a workpiece holder assembly, the apparatus comprises a chamber that at least partially defines a processing space for generating plasma to effect a plasma treatment of a workpiece. The apparatus further comprises a base assembly that at least partially defines a lower end of the chamber. An inner perimeter of the base assembly defines an opening in the base assembly. The apparatus further comprises a workpiece holder assembly that is positioned, at least in part, within the opening in the base assembly. The workpiece holder assembly includes a workpiece holder body configured with an outer perimeter and an upper surface. The upper surface is configured to receive a workpiece. One or more heating elements also form the workpiece holder assembly and are in contact with, at least in part, the workpiece holder body. The inner perimeter of the base assembly and the outer perimeter of the workpiece holder body define a gap that circumscribes, at least in part, the workpiece holder body and thermally isolates the base assembly from the workpiece holder body.

In an example method relating to monitoring the cooling of a plasma treated workpiece, the workpiece is positioned at an apparatus configured to perform the plasma treatment. When the plasma treatment is complete, the workpiece is positioned at an unheated cooling station equipped with a temperature sensor. Via the temperature sensor, it is determined that a temperature of the workpiece is below a threshold value. Based on determining that the temperature is below the threshold value, the workpiece is moved away from the cooling station.

In an example system relating to monitoring the cooling of a plasma treated workpiece, the system comprises a transport apparatus, a plasma treatment apparatus, and an unheated cooling station. The plasma treatment apparatus is configured to perform a plasma treatment and the transport apparatus is configured to receive a workpiece. The unheated cooling station is configured with a temperature sensor. The transport apparatus is configured to position the workpiece at the plasma treatment apparatus and, when the plasma treatment is finished, positon the workpiece at the unheated cooling station. The transport apparatus is further configured to determine, via the temperature sensor, that a temperature of the workpiece is below a threshold value. When it is determined that the temperature is below the threshold value, the transport apparatus is configured to receive the workpiece for further positioning.

In an example apparatus relating to liquid cooling a base assembly, such as an electrode or other plasma excitation source of the base assembly, of a plasma treatment apparatus, the apparatus comprises a chamber partially defining a processing space. The apparatus also comprises the base assembly, with the base assembly having an upper surface. The upper surface of the base assembly defines, at least in part, a lower end of the chamber and an opening in the base assembly. A heated workpiece holder is positioned within the opening in the base assembly and configured to receive a workpiece. The apparatus further comprises a plasma excitation source that is operable to provide a plasma in the processing space for treating the workpiece. The apparatus further comprises a liquid cooling conduit that is proximate the plasma excitation source and configured to receive a liquid to cool the plasma excitation source.

In an example apparatus relating to a uniform vacuum in a chamber of the apparatus, the apparatus comprises the chamber partially defining a processing space for receiving process gas. The chamber is under vacuum during treatment of the workpiece with plasma. The apparatus further comprises a base assembly defining a lower end of the processing space. The base assembly comprises a workpiece holder having a perimeter and configured to receive the workpiece. The base assembly further comprises a baffle assembly having a perimeter and surrounding the perimeter of the workpiece holder. The base assembly further comprises a chamber base surrounding the perimeter of the baffle assembly. The workpiece holder has an upper surface that defines at least a second portion of the lower end of the processing space. The apparatus comprises a process gas supply port in the chamber for introducing the process gas to the processing space. The apparatus comprises a plasma excitation source, such as an electrode, to provide plasma in the processing space from the process gas for treating the workpiece. The apparatus comprises an exhaust opening extending continuously around an entirety of the perimeter of the baffle assembly for evacuating said processing space during treatment of the workpiece with plasma.

### BRIEF DESCRIPTION OF DRAWINGS

The accompanying drawings, which are incorporated in and constitute a part of this specification, illustrate embodiments and together with the description, serve to explain the principles of the methods and systems:

FIG. 1 illustrates a perspective view of a plasma treatment system according to an embodiment of the present disclosure.

FIG. 2 illustrates a side view of the plasma treatment system according to an embodiment of the present disclosure.

FIG. 3 illustrates a top down view of at least portions of a base assembly of the plasma treatment system according to an embodiment of the present disclosure.

FIG. 4 illustrates an exploded perspective view of components of the plasma treatment system according to an embodiment of the present disclosure.

FIG. 5A illustrates a top down, enlarged view of a portion of the base assembly according to an embodiment of the present disclosure.

FIG. 5B illustrates a perspective, enlarged view of a portion of the base assembly according to an embodiment of the present disclosure.

FIG. 6 illustrates an top down view of an electrode and an example chamber base of the base assembly according to an embodiment of the present disclosure.

FIG. 7 illustrates a top down view of the electrode and portions of the below-positioned chamber base according to an embodiment of the present disclosure.

FIG. 8 illustrates an exploded perspective view of components of the base assembly according to an embodiment of the present disclosure.

FIG. 9 illustrates a perspective cross-sectional view of the base assembly according to an embodiment of the present disclosure.

FIG. 10 illustrates a perspective, enlarged, and cross-sectional view of portions of the base assembly according to an embodiment of the present disclosure.

FIG. 11 illustrates a perspective cross-sectional view of the base assembly according to an embodiment of the present disclosure.

FIG. 12 illustrates an plasma processing system according to an embodiment of the present disclosure.

FIG. 13 illustrates a method flow diagram according to an embodiment of the present disclosure.

### DETAILED DESCRIPTION

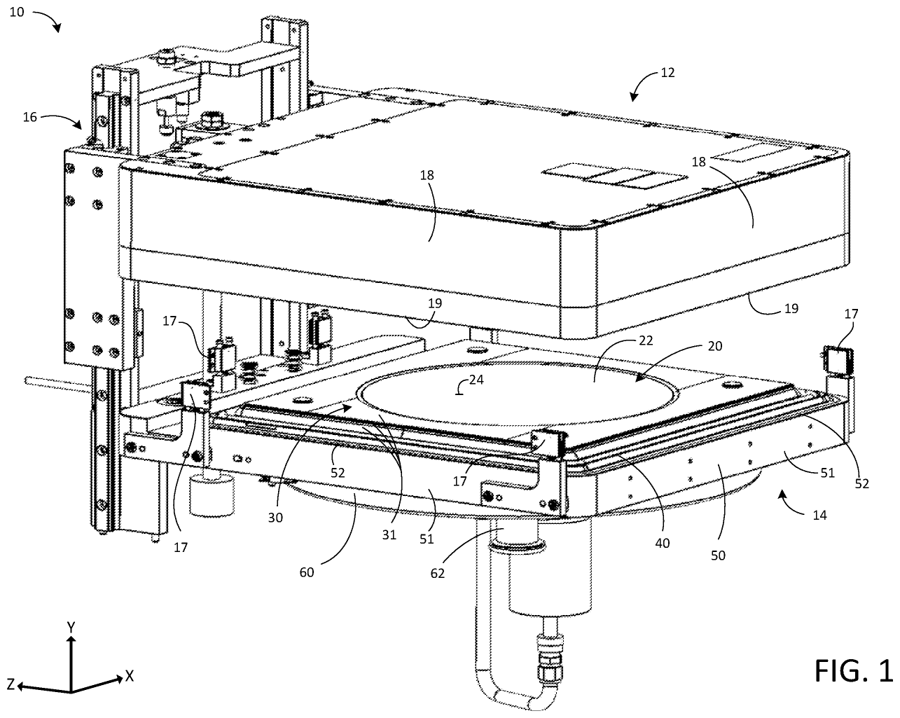

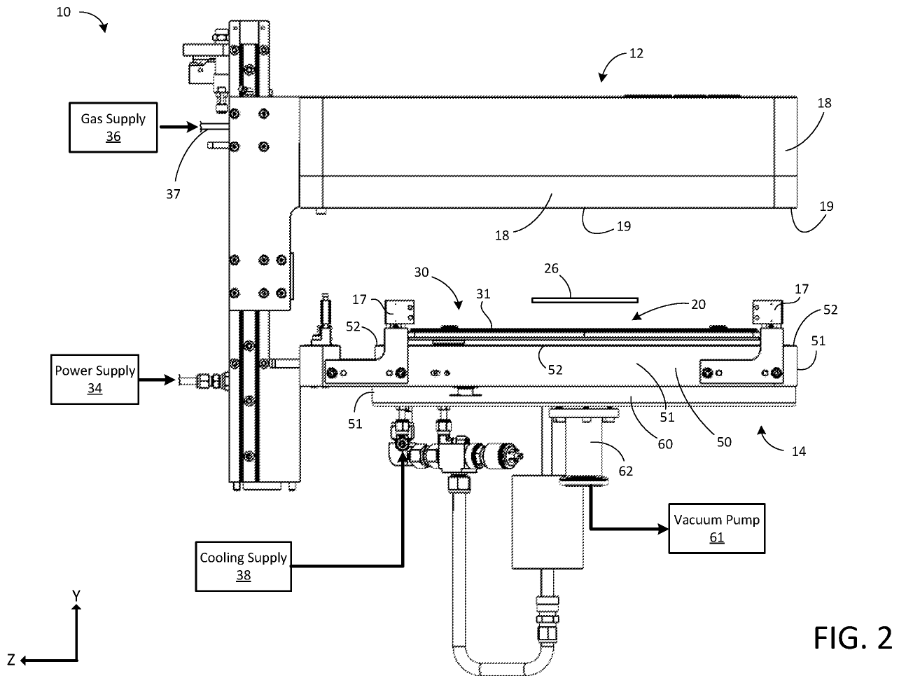

Referring to FIGS. 1 through 3, a plasma treatment system 10 includes a lid assembly 12 positioned above a base assembly 14. The base assembly 14 comprises a workpiece holder assembly 20 with a workpiece holder or chuck 22 configured to support a workpiece 26 upon its upper surface 24. The workpiece 26 is shown in FIG. 2 and positioned suspended above, for purposes of visibility in the figure, the workpiece holder assembly 20. The base assembly 14 further comprises a lift mechanism 30, having one or more stacked lift plates 31, that is configured to selectively lower an unprocessed workpiece 26 onto the workpiece holder 22 and raise a processed workpiece 26 from the workpiece holder 22. The stacked lift plates 31 can be ceramic.

The base assembly 14 further comprises an electrode 40. The lid assembly 12 likewise comprises a counterpart upper electrode (not shown) that, together with the electrode 40 of the base assembly 14, causes the plasma generation needed to treat a workpiece 26. The base assembly 14 yet further comprises a chamber base 50 that supports, generally, various other components of the base assembly 14, including the aforementioned workpiece holder assembly 20, the lift mechanism 30, and the electrode 40. The chamber base 50 comprises one or more vertical sidewalls 51, each having an upper surface 52.

The base assembly 14 additionally comprises a vacuum plate 60 attached to the bottom of the chamber base 50 and configured with a vacuum space via which non-reacted process gas, plasma, and other byproducts of plasma treatment are drawn to a vacuum pump 61. The vacuum pump 61 is operative to maintain the total pressure in the processing space at a sub-atmospheric level low enough to facilitate plasma generation. A vacuum conduit 62 is attached to the bottom of the vacuum plate 60 at a port in the vacuum plate 60 that leads from the vacuum space. The vacuum conduit 62 enables flow of the drawn process gas, plasma, and other byproduct from the vacuum space to the vacuum pump 61.

The lid assembly 12 is mechanically coupled to a positioning device 16 configured to vertically raise and lower the lid assembly 12 relative to the base assembly 14. In the embodiment shown, the positioning device 16 comprises a pair of couplers, each attached to the lid assembly 12 on one side and mounted on one of a pair of vertical rails on the other side. Vertical movement of the couplers on the vertical rails causes likewise movement of the lid assembly 12 towards or away from the base assembly 14. The positioning device 16 illustrated in FIGS. 1 and 2 is but one example configuration and other positioning mechanisms may be used to similar effect.

In a raised position, the lid assembly 12 is out of contact with the base assembly 14, as shown in FIGS. 1 and 2. In a lowered (i.e., closed) position, the lid assembly 12 and the base assembly 14 are in contact with one another. In the embodiment illustrated, the lid assembly 12 comprises vertical sidewalls 18 with each having a lower edge 19. When the lid assembly 12 is lowered into contact with the base assembly 14, the lower edges 19 of the sidewalls 18 of the lid assembly 12 and the corresponding upper surfaces 52 of the sidewalls 51 of the chamber base 50 are in flush engagement with one another. The flush engagement of the sidewalls 18 of the lid assembly 12 and the sidewalls 51 of the chamber base 50 form a seal between the lid assembly 12 and the base assembly 14. The flush engagement of the sidewalls 18 of the lid assembly 12 and the sidewalls 51 of the chamber base is just one example configuration for forming a seal between the lid assembly 12 and the base assembly 14 and the disclosure is not so limited.

When the lid assembly 12 is lowered into flush engagement with the base assembly 14 to form a seal therebetween, a chamber is defined by the interior dimensions of the lid assembly 12 and the base assembly 14. A top portion of the chamber may be defined by one or more components of the lid assembly 12. The upper electrode, a bottom surface of the upper electrode in particular, may at least partially define the top portion of the chamber. In addition, inner surfaces of one or more of the sidewalls 18 of the lid assembly 12 may further at least partially define the top portion of the chamber.

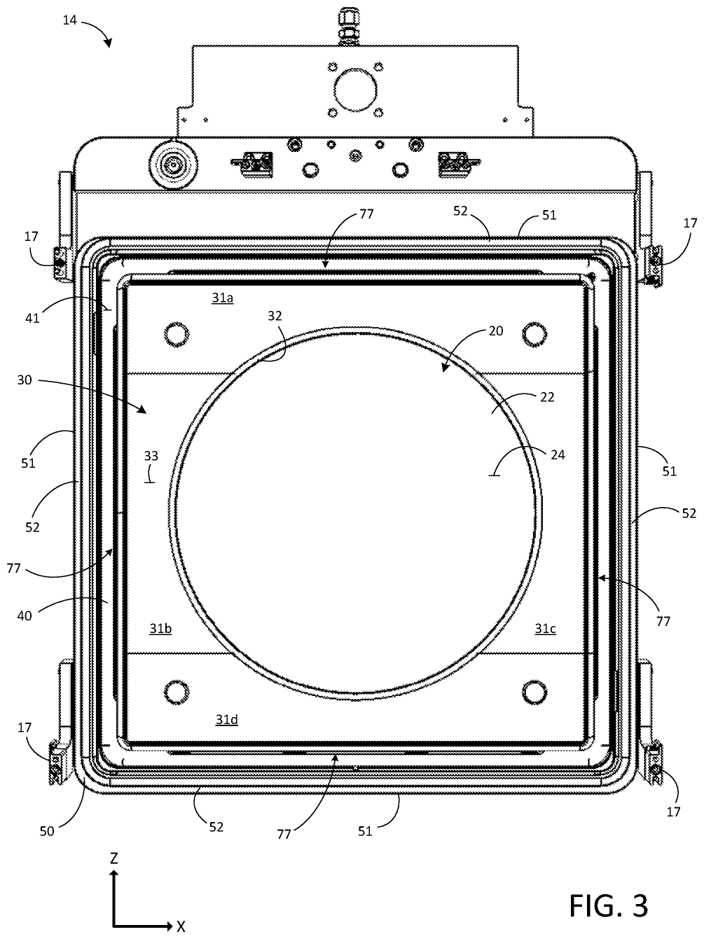

A bottom portion of the chamber may be generally defined by upper surfaces of one or more components of the base assembly 14, as best seen in the top down view of FIG. 3. The bottom portion of the chamber may be at least partially defined by an upper surface 24 of the workpiece holder 22. A first portion of the bottom portion of the chamber may be at least partially defined by the upper surface 24 of the workpiece holder 22 and a second portion of the bottom portion of the chamber may be at least partially defined by an upper surface of the base assembly 14 other than that of the workpiece holder 22. One or more of the stacked lift plates 31 of the lift mechanism 30 may further at least partially define the bottom portion of the chamber. For example, the upper surface 33 of the uppermost lift plate 31 of the one or more stacked lift plates 31 may at least partially define the bottom portion of the chamber. In another embodiment, the baffle plate 70 may also at least partially define the bottom portion of the chamber. In addition, the electrode 40 of the base assembly 14 may also at least partially define the bottom portion of the chamber. The electrode 40 is partially covered on the electrode's 40 upper surface 41 by the one or more stacked lift plates 31 in the illustrated embodiment. Nonetheless, the upper surface 41 of the exposed outer periphery of the electrode 40 may at least partially define the bottom portion of the chamber. Further, the chamber base 50 may at least partially define the bottom portion of the chamber, particularly any exposed upper surfaces of the chamber base 50.

In some embodiments, the lift mechanism 30 may be absent or replaced with another type of lift mechanism. In such an embodiment, the bottom portion of the chamber may be at least partially defined by an otherwise topmost component of the base assembly 14. For example, a base assembly 14 with such a configuration may comprise a baffle plate the same as or similar to the baffle plate described herein. In another example, the lift plates 31 may be replaced by a stationary plate or a stationary component of another type. The stationary plate or other stationary component may be configured with a flat or substantially flat upper surface, for example. The flat or substantially flat upper surface may at least partially define the bottom portion of the chamber.

When so defined by the sealed engagement of the lid assembly 12 and the base assembly 14, the processing space is suitable for plasma processing a workpiece 26 positioned therein. During processing of a workpiece 26, power from a power supply 34 is applied between the electrode 40 of the base assembly 14 and the upper electrode of the lid assembly 12 and produces an electromagnetic field in the processing space. The electromagnetic field excites the atoms or molecules of process gas (provided by a gas supply 36) present in the processing space to a plasma state, which is sustained by the application of power from the power supply 34 for the duration of the plasma treatment.

Constituent species from the plasma contact and interact with exposed material on the workpiece 26 to perform the desired surface modification. The plasma is configured to perform the desired surface modification of the workpiece 26 by selecting parameters such as the chemistry of the process gas, the pressure inside the processing region, and the amount of power and/or frequency applied to the electrodes. The processing system may include an end point recognition system (not shown) that automatically recognizes when a plasma process (e.g., an etching process) has reached a predetermined end point or, alternatively, plasma processes may be timed based upon an empirically-determined time of a process recipe.

As noted, the base assembly 14 includes a workpiece holder assembly 20 comprising a workpiece holder 22 configured to support a workpiece 26 during plasma treatment. For example, the upper surface 24 of the workpiece holder 22 may support the workpiece 26. The workpiece holder assembly 20 is further configured to transfer heat to the workpiece 26 supported by the workpiece holder 22, such as before and/or during plasma treatment of the workpiece 26. Accordingly, the workpiece holder 22 is itself heated. To this end, the workpiece holder assembly 20 comprises one or more heating elements positioned in proximity to, in contact with, or at least partially embedded within the workpiece holder 22. In some embodiments, the workpiece holder 22 may not be heated and thus the heating elements may be omitted from the workpiece holder assembly 20.

As also already noted, the base assembly 14 may further comprise a lift mechanism 30 that is configured to selectively lower a held workpiece 26 onto the workpiece holder 22, such as in anticipation of plasma treatment. The lift mechanism 30 is likewise configured to selectively raise a workpiece 26 from the workpiece's 26 position on the workpiece holder 22, such as upon completion of plasma treatment. The lift mechanism 30 may comprise the one or more stacked lift plates 31 having an inner perimeter 32 (collectively or individually). One or more of the lift plates 31 may be formed in two or more segments that are each separately movable. For example, the top lift plate 31 shown in FIG. 3 is configured with segments 31a-d. In an example, the segments 31a, 31b, and 31d may be raised to lift a workpiece 26 from the workpiece holder 22 while the segment 31c remains stationary.

One or more of the lift plates 31 may each define a central opening 35 in the respective lift plate 31. The opening 35 is sized according to the size of an anticipated workpiece 26 such that the outer periphery of the workpiece 26 is supported by the lift plate 31 at the inner perimeter 32 (or at least a portion thereof) of the lift plate's 31 opening 35. When moved into the lift plates' 31 lowermost position, as shown in FIGS. 1 and 2, at least an upper portion of the workpiece holder 22 is positioned within the opening(s) 35 of the lift plate(s) 31. If supporting a workpiece 26 when moved into this lowermost position, the workpiece 26 will be left to rest upon the workpiece holder 22, ready for plasma treatment. In some embodiments, the upper surface 24 of the workpiece holder 22 may be even with the upper surface 33 of the topmost lift plate 31. In other embodiments, the workpiece holder 22 may protrude slightly from the opening 35 of the topmost lift plate 31. To remove the workpiece 26 from the workpiece holder 22, one or more of the lift plates 31 are raised from the lowermost position. The rim of the workpiece 26 is caught and raised by at least a portion of the inner perimeter 32 of the opening 35 of at least one of the raised lift plates 31. The base assembly 14 is configured with one or more position sensors 17, such as a laser sensor, to detect a position of one or more of the lift plates 31 and/or the workpiece 26 while the same is raised or lowered by the lift mechanism 30.

The plasma treatment system 10 comprises a cooling supply 38 that feeds a cooling system of the base assembly 14, such as one or more cooling conduits. The one or more cooling conduits may be embedded in one or more components of the base assembly 14, such as the electrode 40.

In an example plasma treatment operation of a subject workpiece 26, the lid assembly 12 is in the raised position and the workpiece 26 is positioned on the workpiece holder 22, such as by the lift mechanism 30. The lid assembly 12 is lowered to come into contact with the base assembly 14 and form a seal between the two. A chamber, providing a processing space, is thereby formed. The chamber is held under vacuum by the vacuum pump 61. A process gas from the gas supply 36 is provided to the processing space of the chamber via a process gas inlet 37 of the lid assembly 12. The upper electrode of the lid assembly 12 and the electrode 40 of the base assembly 14 are activated by the power supply 34, thereby causing plasma to be created in the processing space from the process gas. When plasma treatment of the workpiece 26 is complete, the process gas, plasma, and other plasma byproduct are evacuated from the chamber by the vacuum pump 61.

The process gas, plasma, and other plasma byproduct are evacuated via one or more channels or flow paths formed within and/or between various components of the base assembly 14. An example flow path may comprise discrete vertical portions and horizontal (i.e., lateral) portions. The example flow path may alternate between the vertical portions and the horizontal portions. A vertical portion of the flow path may be defined by a vertical passage through one or more of the components of the base assembly 14. A horizontal portion of the flow path may be defined between two components of the base assembly 14. A horizontal length of one or more of the horizontal portions of the flow path is greater than a vertical height of one or more of the vertical portions of the flow path. The horizontal lengths of two or more of the horizontal portions of the flow path are greater than both of the vertical heights of two or more of the vertical portions of the flow path.

The lid assembly 12 is lifted from the base assembly 14 and the plasma treated workpiece 26 is removed. Further iterations of the plasma treatment operation may be then performed.

Plasma Chamber with Uniform Vacuum

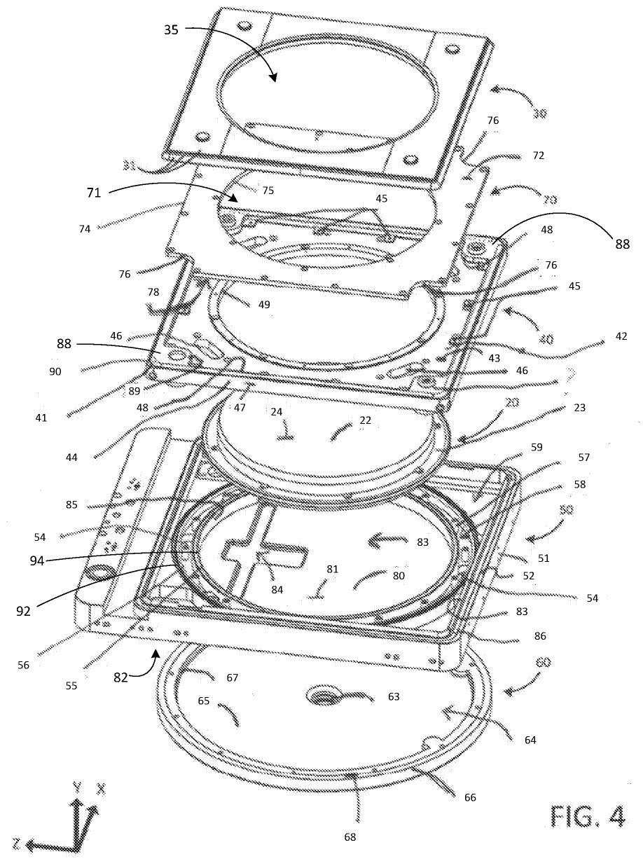

With reference to FIGS. 4 through 8, in which like reference numerals refer to like features in the Figures, aspects of the plasma treatment system 10 relating to a uniform vacuum provided within the plasma chamber formed by components of the plasma treatment system 10 shall now be described, at least in part. Description of such aspects of the plasma treatment system 10 is not confined to this subsection. The same, additional, or alternative aspects of the plasma treatment system 10 relating to a uniform vacuum provided within the plasma chamber may be found throughout the disclosure.

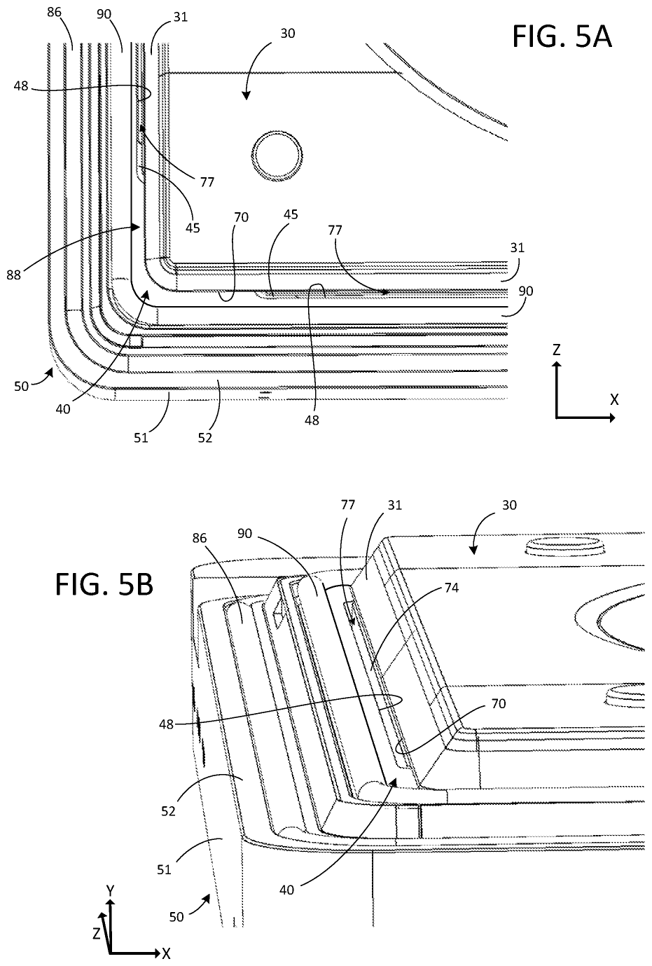

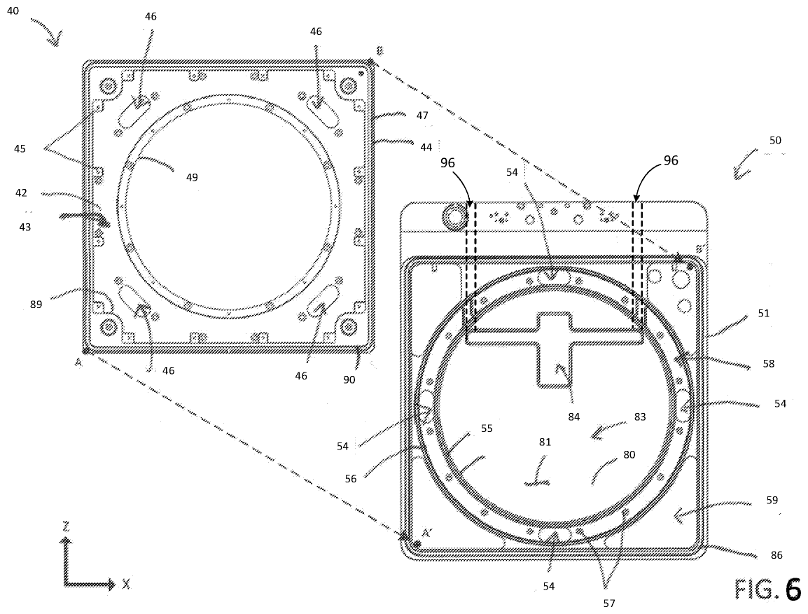

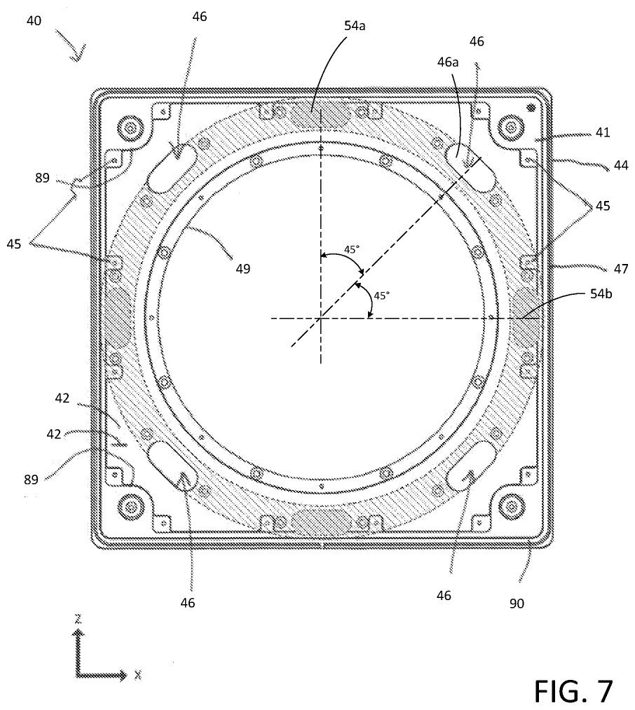

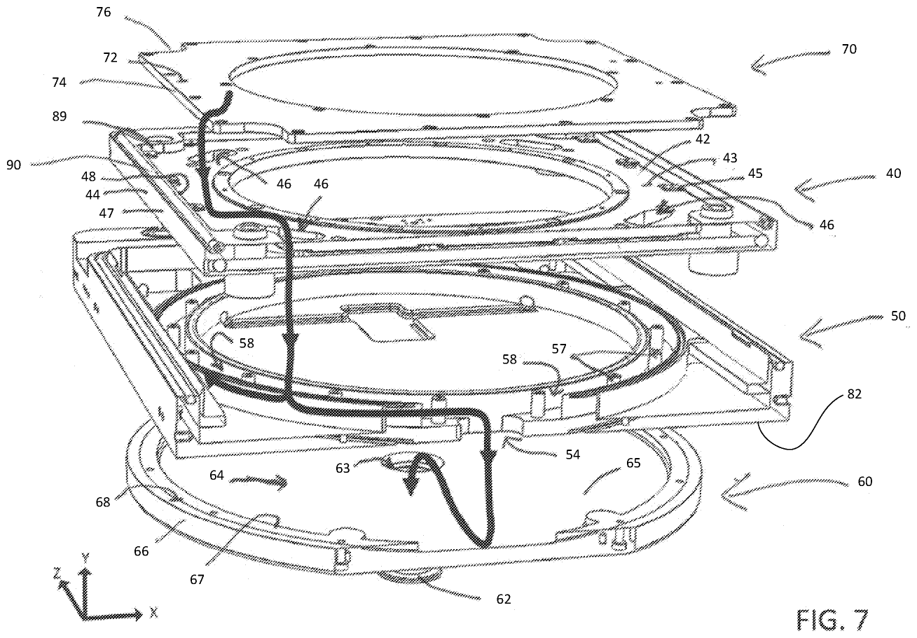

FIG. 4 illustrates a vertically-exploded perspective view of several components of the base assembly 14, including the lift mechanism 30, a baffle plate 70, the workpiece holder assembly 20, the chamber base 50, and the vacuum plate 60. Various connectors and the like have been excluded from FIG. 4 for clarity of illustration. FIGS. 5A and 5B illustrate enlarged views of portions of the base assembly 14, including one or more gaps 77 that are defined between the baffle plate 70 and the electrode 40. FIG. 6 illustrates top down views of the electrode 40 and the chamber base 50 showing the fit between the electrode 40 and the chamber base 50. FIG. 7 illustrates a top down view of the electrode 40 along with portions of the chamber base 50 shown below the electrode 40 in shadow. FIG. 8 illustrates a vertically-exploded perspective view of the baffle plate 70, the electrode 40, the chamber base 50, and the vacuum plate 60. FIG. 8 further illustrates a flow path of process gas, plasma, and other plasma byproduct through the aforementioned components.

Beginning with the chamber base 50, the upper portions of the chamber base 50 generally support, at least in part, the electrode 40. The coupling between the chamber base 50 and the electrode 40 may be limited by a thermal break therebetween. One or more O-rings (e.g., a first channel O-ring 94 and a second channel O-ring 92) or other type of sealing element substantially provide the points of contact between the chamber base 50 and the electrode 40, but otherwise allow a space (i.e., a thermal break) therebetween. The vacuum plate 60 is secured to the underside of the chamber base 50. Namely, the vacuum plate 60 is connected to a bottom surface 82 of a floor 80 of the chamber base 50. As already noted, the chamber base 50 comprises the outer side walls 51, each having the upper surfaces 52 and inner surfaces 53. The sidewalls 51 generally enclose, to the sides, the interior components of the chamber base 50.

The chamber base 50 further comprises a channel 58 configured to accommodate a flow of vacuum-drawn process gas, plasma, and other plasma byproduct originated from a plasma treatment in the processing space of the chamber. The channel 58 may be formed as a generally-enclosed conduit and configured to cause a lateral (i.e., along the X and Z axes) flow of the process gas, plasma, and other plasma byproduct within the chamber base 50. The channel 58 may receive the flow of process gas and plasma from one or more openings in a top surface of the channel 58. The flow of process gas and plasma may exit the channel 58 via one or more openings in the bottom surface of the channel 58. At least one top opening to the channel 58 may be offset, along a circumference of the channel 58, from at least one bottom openings from the channel 58. Being offset from one another, the at least one top opening and the at least one bottom opening do not share a vertical (Y) axis. For example, two or more of the top openings to the channel 58 may be offset from two or more of the bottom openings from the channel 58. As another example, each of the top openings to the channel 58 may be offset from each of the bottom openings from the channel 58.

In the embodiment shown in at least FIGS. 4 through 8, the sides of the channel 58 are defined by concentric circular structures: an outer circular structure 56 and an inner circular structure 55, the inner circular structure 55 in a spaced relationship with the outer circular structure 56. The channel 58 is similarly formed as a continuous (in the X and Z axes) circular channel. The bottom of the channel 58 is defined, at least in part, by an upper surface 81 of the floor 80 of the chamber base 50. The top of the channel 58 is defined, at least in part, by a bottom surface (not shown) of the electrode 40. The first channel O-ring 94 and the second channel O-ring 92 are positioned at the top of the outer circular structure 56 and the inner circular structure 55, respectively. When the base assembly 14 is assembled, the first channel O-ring 94 and the second channel O-ring 92 provide a seal between the electrode 40 and the outer circular structure 56 and the inner circular structure 55, respectively.

The channel 58 is configured with one or more downward-facing passages 54 defined by, at least in part, and passing through the floor 80 of the chamber base 50. The one or more passages 54 allow flow of the vacuum-drawn process gas, plasma, and other plasma byproduct from the channel 58 to a vacuum space 64 defined by the vacuum plate 60. The one or more passages 54 may be formed at different locations in the channel 58. For example, the one or more passages 54 may be distributed evenly about the circumference of the channel 58. For example, two passages 54 may be located opposite one another in the channel 58. That is, the two passages 54 may be offset from each other by about 180 degrees. As another example, three passages 54 may located in the channel 58 at about 120 degree intervals. Alternatively, the one or more passages 54 may be located at irregular intervals around the channel 58. In the embodiment shown in at least FIGS. 4 through 8, the channel 58 is configured with four passages 54 that are located at about 90 degree intervals around the channel 58. The channel 58 is further configured with one or more spacers 57 positioned around the circumference of the channel 58. The spacers 57 may cause turbulence in the flow of process gas, plasma, and other plasma byproducts in the channel 58, thereby facilitating the uniformity of the vacuum in the chamber.

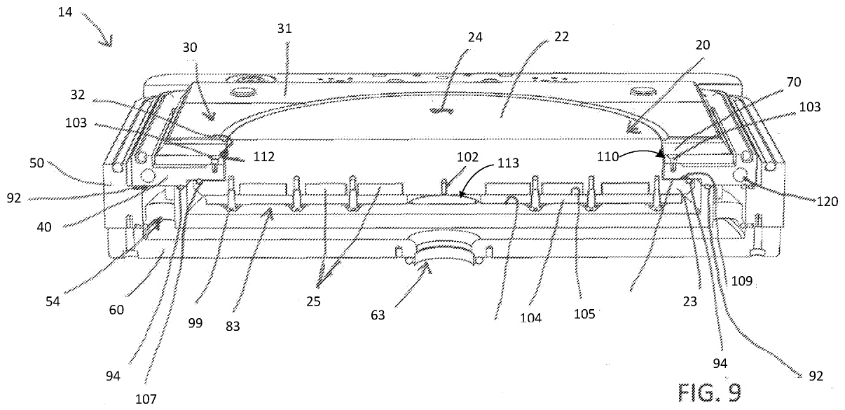

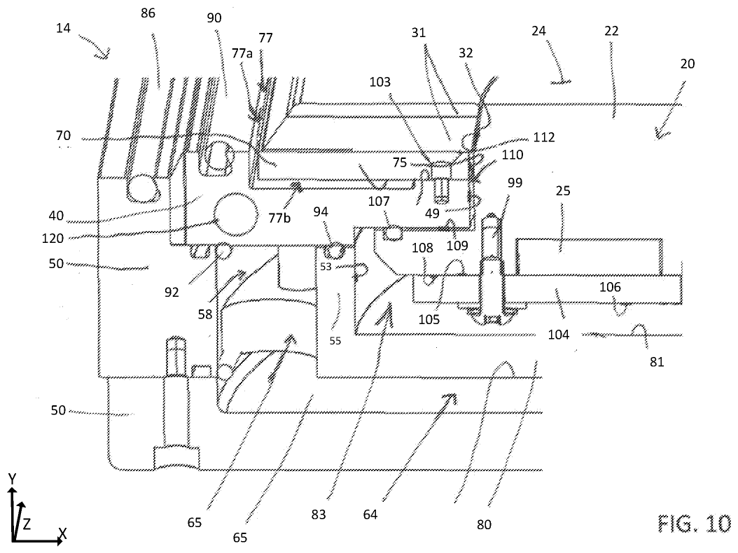

The chamber base 50 is configured with an interior space 83 that is maintained at ambient pressure during a plasma treatment. The interior space 83 is defined at the sides by an inner surface 85 of the inner circular structure 55. The interior space 83 is defined at the bottom by the upper surface 81 of the floor 80 and at the top primarily by the workpiece holder assembly 20 (e.g., a bottom surface 106 of an insulator piece 104 shown in FIGS. 9 and 10) and, to a lesser extent, the electrode 40. Within the interior space 83, the floor 80 of the chamber base 50 is configured with an indentation 84. The indentation opens to a pair of bores 96 (FIG. 6.) formed in the body of the chamber base 50 and exiting to the ambient environment, thereby allowing the interior space 83 to be held at ambient pressure.

The workpiece holder assembly 20 and the electrode 40 are positioned generally vertically above the chamber base 50. The workpiece holder assembly 20 is coupled to the electrode 40 and the electrode 40 is coupled to the chamber base 50. The workpiece holder assembly 20 is coupled to the electrode 40 by coupling a flange 23 of the workpiece holder assembly 20 with the electrode 40 at an inner perimeter 49 of a central opening in the electrode, such that the flange 23 is proximate to—but not in contact with—the underside of the electrode 40. When so coupled, at least an upper portion of the workpiece holder 22 protrudes through the central opening of the electrode 40. The electrode 40 is coupled, in turn, to the chamber base 50 such that an outer surface 47 of a sidewall 44 of the electrode 40 is spaced flush against the inner surface 53 of the sidewall 51 of the chamber base 50. When the workpiece holder assembly 20 is coupled to the electrode 40 and the electrode 40 is coupled to the chamber base 50, the workpiece holder assembly 20 is positioned generally above, but not in direct contact with, the floor 80 of the chamber base 50, thus defining the upper bounds of the interior space 83 of the chamber base 50.

The electrode 40 is configured with a recessed floor 42 having an upper surface 43. The outer bounds of the floor 42 are defined, at least in part, by the inner surface 48 of the sidewall 44 of the electrode 40. The outer bounds of the floor 42 are further defined, at least in part, by convex edges 89 of corresponding corner elements 88. The upper surfaces of the corner elements 88 are flush with the upper surface of the sidewall 44. The corner elements 88 may be considered as comprising part of the sidewall 44. One of the corner elements 88 may be a lift spring assembly 88a.

One or more raised connectors or mounting bosses 45 are positioned at the periphery of the recessed floor 42, next to the inner surface 48 of the sidewall 44. In some embodiments, the raised connectors 45 (or similar raised structures) may be positioned elsewhere on the recessed floor 42. By coupling to the raised connectors 45, the baffle plate 70 is coupled to the electrode 40. A height of the raised connectors 45 may be at a vertical midway point between the recessed floor 42 and the upper surface of the sidewall 44 of the electrode 40. The baffle plate 70 is further coupled with the electrode 40, via connectors 103 (FIGS. 9 and 10), proximate an inner perimeter 75 of the baffle plate 70 and the inner perimeter 49 of the electrode 40. The portion of the electrode 40 configured to receive the connectors 103 is raised from the recessed floor 42 at a same or similar height as that of the raised connectors 45. Being raised from the recessed floor 42, the raised connectors 45 may allow an interior space 97 to be defined between the upper surface 43 of the recessed floor 42 and a bottom surface 78 (not fully visible in FIGS. 4 through 8) of the baffle plate 70. The interior space 97 provides for a lateral (along the X and Z axes) flow, at least in part, of process gas, plasma, and other plasma byproduct from a gap 77, formed between an outer perimeter 74 of the baffle plate 70 and the sidewall 44 of the electrode 40, and one or more passages 46 formed in the recessed floor 42.

The recessed floor 42 defines the one or more passages 46, facing downwards, through the electrode 40. The embodiment shown in FIGS. 4 through 8 comprises four passages 46, although the disclosure is not so limited. For example, the recessed floor 42 may define one passage 46, two passages 46, or more than two passages 46. The passages 46 provide for the downward flow of the vacuum-drawn process gas, plasma, and other plasma byproduct from the interior space 97 of the electrode 40 to the channel 58 of the chamber base 50. The passages 46 may be positioned at various locations in the recessed floor 42. For example, the passages 46 may be positioned at regular intervals around a theoretical circumference centered at the opening defined by the inner perimeter 49 of the electrode 40. The center of this theoretical circumference may be considered the center of the electrode 40. As an example, an embodiment with two passages 46 may have the two passages 46 positioned opposite each other (i.e., at about 180 degrees from each other). An embodiment with three passages 46 may have the three passages 46 positioned at about 120 degree intervals around the theoretical circumference. An embodiment with four passages 46 may position the passages 46 at about 90 degree intervals around theoretical circumference.

As noted above with respect to the passages 54 located in the channel 58 of the chamber base 50, the passages 46 of the electrode 40 are positioned so as to be laterally offset from the passages 54 (e.g., no common vertical axis). For example, at least one of the passages 46 may be offset from at least one of the passages 54. As another example, at least two of the passages 46 may be offset from at least two of the passages 54. Further, each of the passages 46 of the electrode 40 may be offset from all of the passages 54 of the chamber base 50, such as in the embodiment shown in FIGS. 4 through 8.

The offset between the passages 46 of the electrode 40 and the passages 54 of the chamber base 50 may be referred to by a degree of relative offset with respect to the center of the electrode 40 and/or a center of a circumference defined by the inner circular structure 55 or the outer circular structure 56 of the chamber base 50 (e.g., the center of the chamber base 50 or at least the portions of the chamber base 50 relating to the flow of process gas, plasma, and plasma byproduct through the base assembly 14). For example, the degree of relative offset may be about 45 degrees, as is the case in the embodiment shown in FIGS. 4 through 8. As other examples, the degree of relative offset may be at least or at about 15 degrees, at least or at about 30 degrees, at least or at about 60 degrees, at least or at about 75 degrees, at least or at about 90 degrees, at least or at about 120 degrees, or at least or at about 180 degrees. The relative offset may refer to the relative offset of at least one passage 46 of the electrode 40 and a nearest passage 54 of the chamber base 50 or vice versa. The relative offset may refer to the relative offset of at least one passage 46 of the electrode 40 and two nearest passages 54 of the chamber base 50 or vice versa. Either case may apply to the embodiment shown in FIGS. 4 through 8.

The baffle plate 70 may be coupled to the raised connectors 45 of the electrode 40 to couple the baffle plate 70 generally with the electrode 40. When coupled with the electrode 40, an upper surface 72 of the baffle plate 70 is flush with the upper surface 41 of the electrode 40, including an upper surface of the raised corner 88. The baffle plate 70 comprises the inner perimeter 75 that defines an opening 71 at the center of the baffle plate 70. The inner perimeter 75 of the baffle plate 70 vertically aligns substantially with the inner perimeter 49 of the electrode 40. The opening 71 is configured to accommodate the workpiece holder 22.

The outer perimeter 74 of the baffle plate 70 includes a concave edge 76 that generally corresponds in shape with the convex edge 89 of the raised corner 88. The outer perimeter 74 of the baffle plate 70 is proximate to—but not in direct contact with—the inner surface 48 (which may include the convex edge 89) of the sidewall 44 of the electrode 40. In some embodiments, the entirety of the outer perimeter 74 is proximate to but not in direct contact with the inner surface 48 of the sidewall 44. In other embodiments, the outer perimeter 74 is partially in contact with the inner surface 48 of the sidewall 44 and partially proximate to the inner surface 48 of the sidewall 44 but not in direct contact with the inner surface 48 of the sidewall 44. In yet other embodiments, the majority of the outer perimeter 74 is proximate to but not in contact with the inner surface 48 of the sidewall and a minority of the outer perimeter 74 is in contact with the inner surface 48 of the sidewall 44.

The spatial relationship between the outer perimeter 74 of the baffle plate 70 and the inner surface 48 of the sidewall 44 of the electrode 40 defines the gap 77 through which process gas, plasma, and other plasma byproduct flow from the processing space of the formed chamber. The gap 77 may be elongated along the length (or portion thereof) of the corresponding side of the baffle plate 70 and/or electrode 40.

In some embodiments, the gap 77 on one side of the coupled baffle plate 70 and electrode 40 may be elongated substantially the entire length of the side such that this gap 77 is contiguous with a second gap 77 of the adjoining side. The gap 77 on each of the sides of the coupled baffle plate 70 and electrode 40 may be so configured, thus providing a gap 77 that fully extends around, without break, the outer perimeter 74 of the baffle plate 70. In other embodiments, a gap 77 is elongated along the majority of the length of a side of the coupled baffle plate 70 and electrode 40, but is not contiguous with a second gap 77 of an adjoining side. Thus the gap 77 (here collectively referring to the respective gaps 77 of each side of the coupled baffle plate 70 and electrode 40) may extend around the majority of the outer perimeter 74 of the baffle plate 70 but may comprise breaks in the gap 77. In yet other embodiments, a gap 77 (referring collectively to a broken series of gaps 77) corresponding to a side of the coupled baffle plate 70 and electrode 40 does not extend the majority of the length of the side without one or more breaks. But the gap 77 (again referring collectively to a broken series of gaps 77) nonetheless may cover the majority of the outer perimeter 74 of the baffle plate 70.

In the embodiment shown in FIGS. 4 through 8, the gap 77 is formed around the majority of the outer perimeter 74 of the baffle plate 70 but is broken at the corners of the coupled baffle plate 70 and electrode 40. Specifically, the corners of the lift mechanism 30 (e.g., a lift plate 31) is positioned over the raised corners 88 of the electrode 40, thus preventing direct flow of process gas and plasma through the space between the convex edge 89 of the raised corner 88 and the concave edge 76 of the baffle plate 70 and into the interior space 97 of the electrode 40. Additionally, each of the raised connectors 45 of the electrode 40 effectively cause a brief break in the gap 77.

The gap 77 may be configured as, when viewed in vertical cross section of the base assembly 14, a vertical portion 77a (see FIG. 10) and a horizontal portion 77b (also see FIG. 10). The vertical portion 77a of the gap 77 is defined by the outer perimeter 74 of the baffle plate 70 and the inner surface 48 of the sidewall 44 of the electrode 40. When viewed in the cross-section seen in FIG. 10, the vertical portion 77a is elongated along the Y axis, but is confined along the X axis. Thus the vertical flow of the process gas, plasma, and other plasma byproducts is facilitated in the vertical portion 77a of the gap 77. But any horizontal flow in the vertical portion 77a is severely limited. The horizontal portion 77b of the gap is defined by the recessed floor 42 of the electrode 40 and the bottom surface 78 of the baffle plate 70. The horizontal portion 77b of the gap 77 may correspond substantially with the interior space 97 between the electrode 40 and the baffle 70, particularly in the inward direction from the inner surface 48 of the sidewall 44 to the inner perimeter 49 of the electrode 40. In contrast to the vertical portion 77a, the horizontal portion 77b of the gap 77 is elongated along the horizontal X axis (when view in the cross section of FIG. 10) but not the vertical Y axis. Thus flow of the process gas, plasma, and other plasma byproducts in the horizontal portion 77b of the gap 77 is facilitated along the horizontal X axis but is severely limited along the vertical Y axis.

The dimensions of the gap 77 may be configured to alter the flow of process gas and plasma through the base assembly 14. For example, a width of 0.5 mm to 2 mm (from the baffle plate 70 to the electrode 40) of the gap 77 may be decreased to constrict the flow of process gas, plasma, and other plasma byproduct while the width of the gap 77 may be increased to increase the flow of process gas, plasma, and other plasma byproduct. The lengthwise dimensions of the gap 77 may be configured to similar effect.

The lift mechanism 30 is coupled to the baffle plate 70 and or electrode 40, with the bottom surface of the lowermost lift plate 31 in contact with the upper surface 72 of the baffle plate 70 and the upper surfaces of the raised corners 88 of the electrode 40. The corners of the lift mechanism 30 cover the space defined between the convex edge 89 of the raised corner 88 and the concave edge 76 of the outer perimeter 74 of the baffle plate 70. The central opening 35 is defined in the lift mechanism 30 and is configured to accommodate, at least in part, the workpiece holder 22.

Below the chamber base 50, an upper surface 68 of a sidewall 66 of the vacuum plate 60 is coupled to the bottom surface 82 of the chamber base 50. A vacuum space 64 is defined by the bottom surface 82 of the chamber base 50, the inner surface 67 of the sidewall 66, and the floor 65 of the vacuum plate 60. The vacuum space 64 is configured to receive process gas, plasma, and other plasma byproduct from the channel 58 via one or more of the passages 54. The floor 65 of the vacuum plate 60 is configured with a port 63 (e.g., only a single port 63) to allow flow of the process gas, plasma, and other plasma byproduct in the vacuum space 64 to the vacuum pump 61.

With particular reference to FIGS. 5A and 5B, enlarged views of a corner of the base assembly 14 are illustrated. FIG. 5A illustrates a substantially top down view and FIG. 5B illustrates a perspective view. FIGS. 5A and 5B are provided, at least in part, for clarity of illustration of at least the spaced relationship between the baffle plate 70 and the electrode 40 that defines the gap 77. For example, FIGS. 5A and 5B show that the inner surface (with respect to the center of the baffle plate 70, for example) of the gap 77 is defined by the outer perimeter 74 of the baffle plate 70. The outer surface of the gap 77 is defined by the inner surface 48 of the sidewall 44 of the electrode 40. FIG. 5A further shows two of the raised connectors 45 and that this particular raised connector 45 expands the break in the gap 77 caused by the raised corner 88. An electrode O-ring 90 or other type of sealing element is situated at the upper surface of the sidewall 44 of the electrode 40. The electrode O-ring 90 creates, at least in part, a seal with one or more components of the lid assembly 12. A chamber base O-ring 86 or other type of sealing element is situated at the upper surface 52 of the sidewall 51 of the chamber base 50. The chamber base O-ring 86 creates, at least in part, a seal with a counterpart surface of the lid assembly 12.

With particular reference to FIG. 6, top down views of the electrode 40 and chamber base 50 are illustrated. FIG. 6 illustrates, at least in part, the relative positioning of the electrode 40 and the chamber base 50. The lower left corner of the electrode 40 (as illustrated) is marked with reference character A and the upper right corner of the electrode 40 is marked with reference character B. The lower left corner of the chamber base 50 (as illustrated) is marked with reference character A′ and the upper right corner of the chamber base 50 is marked with reference character B′. When the electrode 40 and the chamber base 50 are coupled, the corners of the electrode 40 marked A and B align with the corners of the chamber base 50 marked A′ and B′, respectively. FIG. 6 further illustrates the bores 96 opening the interior space 83 of the chamber base 50 to the ambient environment, thereby allowing for wiring.

With particular reference to FIG. 7, a top down view of the electrode 40 is illustrated. FIG. 7 further illustrates the channel 58 and the passages 54 of the chamber base 50, which are illustrated in shadow to reflect that the chamber base 50 is situated below the electrode 40 in the base assembly 14. As is shown, the electrode 40 is configured with four passages 46 and the chamber base 50 is likewise configured with four passages 54. The channel 58 is positioned to substantially correspond with the positions of the passages 46 directly above the channel 58. Thus, the vacuum-drawn process gas, plasma, and other plasma byproduct in the interior space 97 of the electrode 40 moves downward through the passages 46 and into the channel 58. Once in the channel 58 and by virtue of the relative offset between the passages 46 of the electrode 40 and the passages 54 of the chamber base 50, the process gas, plasma, and other plasma byproduct must flow clockwise and/or counterclockwise (according to a top down view of the chamber base 50) in the channel 58.

FIG. 7 also shows an example spacing of the passages 46 of the electrode 40, an example spacing of the passages 54 of the chamber base 50, and an example relative offset of the passages 46 of the electrode 40 and the passages 54 of the chamber base 50. In these examples, the passages 46 of the electrode 40 are uniformly spaced at 90 degree intervals. The passages 54 of the chamber base 50 are likewise uniformly spaced at 90 degree intervals. The relative offset between the passages 46 of the electrode 40 and the passages 54 of the chamber base 50 is forty-five degrees. For example, a passage 54a and a passage 54b are the nearest passages 54 to a passage 46a. Each of the passages 54a and 54b are offset from the passage 46a by forty-five degrees.

FIG. 8 illustrates a vertically-exploded perspective view of the vacuum plate 60, the chamber base 50, the electrode 40, and the baffle plate 70. FIG. 8 further illustrates an example flow path 98 of vacuum-drawn process gas, plasma, and other plasma byproduct through the base assembly 14. Initially, the process gas and plasma are within the processing space of the formed chamber. The process gas, plasma, and other plasma byproduct flow from the processing space and through the gap 77 (not explicitly show in FIG. 8), here represented by the downward turn of the flow path 98 at the outer perimeter 74 of the baffle plate 70. The process gas, plasma and other plasma byproduct flow through the gap 77 to the interior space 97 between the recessed floor 42 and the bottom surface 78 of the baffle plate 70. Due to the low vertical profile of the interior space 97, the flow path 98 is forced in a generally lateral direction. In this example, the process gas and plasma flows laterally to the indicated passage 46 of the electrode 40 and downwards through the passage 46 to the channel 58 of the chamber base 50. In the channel 58, the process gas and plasma my flow in a clockwise direction, a counter-clockwise direction, or a combination thereof. In the illustrated example, at least a portion of the flow path 98 moves counter-clockwise towards the indicated passage 54 of the chamber base 50. Flowing through the passage 54, the process gas, plasma, and other plasma byproduct are drawn into the vacuum space 64 defined by the bottom surface 82 of the chamber base 50, the inner surface 67 of the sidewall 66, and the floor 65 of the vacuum plate 60. The process gas, plasma, and other plasma byproduct in the vacuum space 64 are drawn, by the vacuum pump 61, initially through the port 63 in the vacuum plate 60 and then the vacuum conduit 62.

The base assembly 14 at least in part so-configured and resultant flow paths therethrough (e.g., the flow path 98) may contribute to improved flow characteristics of the processing space and/or the chamber formed by the drawn-together lid assembly 12 and base assembly 14. For example, the improved flow characteristics may include improved uniformity of the process gas, plasma, and other plasma byproducts flow, such as when the process gas, plasma, and other plasma byproducts are vacuum-drawn from the processing space into and through the base assembly 14. In addition, the base assembly 14 configured at least in part according to this disclosure may allow fewer vacuum seals than would otherwise be required because of the single path for exhaust. Further, the base assembly 14 at least in part so-configured may allow for use of a single port access (e.g., the port 63) to evacuate the vacuum space 64 by distributing the vacuum across the vacuum plate 60, acting as a continuous manifold.

### Thermally Isolated Workpiece Holder

With reference to FIGS. 9 and 10, in which like reference numerals refer to like features in the Figures, aspects of the plasma treatment system 10 relating to a thermally insulated workpiece holder assembly (e.g., a chuck) shall now be described, at least in part. Description of such aspects of the plasma treatment system 10 is not confined to this subsection. The same, additional, or alternative aspects of the plasma treatment system 10 relating to a thermally insulated workpiece holder assembly may be found throughout the disclosure.

FIG. 9 illustrates a perspective, cross-sectional view of the base assembly 14. FIG. 10 illustrates a perspective, enlarged, cross-sectional view of a portion of the base assembly 14.

The workpiece holder assembly 20 and proximate components of the base assembly 14 are configured, individually and collectively, to thermally isolate the workpiece holder assembly 20 from the other proximate components of the base assembly 14. That is, the workpiece holder assembly 20 and the proximate components of the base assembly 14 are configured to minimize heat transfer from the workpiece holder assembly 20 to the proximate portions of the base assembly 14. For example, the workpiece holder assembly 20 comprises the workpiece holder 22, one or more heating elements 25 configured to provide heat to the workpiece holder 22, and an insulator piece 104 configured to minimize heat transfer to other components of the base assembly 14 other than the workpiece holder 22. As another example, the workpiece holder assembly 20 and the proximate components of the base assembly 14 are configured, individually or collectively, to maintain a gap 110 between the workpiece holder 22 and the proximate components of the base assembly 14. The gap 110 affords a thermal break between the workpiece holder 22 and the proximate components of the base assembly 14.

The heating elements 25 may comprise one or more resistance heating elements, for example. The heating elements 25 may be situated so as to be in contact with the workpiece holder 22 and effect heat transfer to the workpiece holder 22. In the workpiece holder assembly 20 shown in FIGS. 9 and 10, the heating elements are partially embedded within the workpiece holder 22, such that the bottoms of the heating elements 25 are flush with a top surface 105 of the insulator piece 104. By embedding the heating elements 25 within the workpiece holder 22, heat transfer to the workpiece holder 22 is maximized while minimizing heat loss to other components. For example, the workpiece holder 22 directly absorbs heat from the heating elements 25 from three sides (the inner side, the outer side, and the top) of the heating element 25. The heating elements 25 are formed as a series of concentric rings, although other arrangements are also contemplated. The workpiece holder 22 is equipped with a temperature sensor 102, such as a thermocouple, to measure the temperature of the workpiece holder 22.

The insulator piece 104 is coupled to the workpiece holder 22 with connectors 99, provided in an alternating arrangement with the circular heating elements 25. When coupled, the insulator piece 104 is held generally in flush engagement, via the insulator piece's 104 top surface 105, with the heating elements 25 and the bottom of the workpiece holder 22. The insulator piece 104 may also serve as a bottom cover to the workpiece holder 22 and heating elements 25. In some embodiments, the workpiece holder assembly 20 may be configured with a separate cover that is situated below the insulator piece 104. The insulator piece 104 is configured with a central opening 113 that exposes the temperature sensor 102 to the ambient pressure interior space 83 between the workpiece holder assembly 20 and chamber base 50. The insulator may be configured to withstand at least 230° Celsius. The insulator piece 104 may be formed from Mica, with a thermal conductivity of about 0.69 W/mK and a maximum service temperature of about 982° Celsius.

In some embodiments, the connectors 99 may be clamps, such as metal clamps. The clamps may be made of stainless steel and have a low profile. The clamps may be located under the insulator piece 104. Three clamps may be provided per heating element 25, although any number greater than one of the clamps may be used to secure each heating element 25. Each clamp can also span one or more heating elements 25, such as two heating elements 25. The clamps may improve the interface between the heating elements 25 and the workpiece holder 22, thereby improving the efficiency of heat transfer to the workpiece holder 22. As such, the energy and temperature of the heating elements 25 may be lowered to achieve a desired temperature of the workpiece holder 22.

The workpiece holder 22 is configured with the outer flange 23 by which the workpiece holder 22 is coupled to the electrode 40. When coupled, a top surface 109 of the flange 23 is proximate to—but not in direct contact with—a bottom surface 108 of the electrode 40 near the inner perimeter 49 of the electrode 40. The space between the top surface 109 of the flange 23 and the bottom surface 108 of the electrode 40 provided by such a coupling may form a horizontal portion of the gap 110 between the workpiece holder 22 and other proximate components of the base assembly 14. The flange 23 of the workpiece holder 22 is coupled to the electrode 40 using one or more connectors, such as bolt connectors. The connectors are not visible at the cross-sections illustrated in FIGS. 9 and 10, although the openings in the flange 23 and the electrode 40 for said connectors are shown in FIG. 4.

An O-ring 107 or other type of sealing element is provided between the top surface 109 of the flange 23 and the bottom surface 108 of the electrode 40. The O-ring 107 is made from a material configured to minimize heat transfer. Besides the connectors, the O-ring 107 is an additional point of contact between the workpiece holder 22 and the electrode 40. In the embodiment shown in FIGS. 9 and 10, such points of contact are limited to only the connectors and the O-ring 107. The potential avenues for heat transfer between the workpiece holder 22 and the electrode 40 are likewise limited to the connectors and the first channel O-ring 94. Thus the connectors and the first channel O-ring 94 are configured (in positioning, material, size, etc.) to minimize heat transfer between the workpiece holder 22 (and the workpiece holder assembly 20 at large) and the electrode 40. For example, the O-ring 107 is positioned substantially at the outer perimeter of the flange 23, thereby being positioned at a maximum, almost maximum, or otherwise substantial distance from the heating elements 25.

The gap 110 includes a vertical (or substantially vertical) first portion 110a and a horizontal (or substantially horizontal) second portion 110b. The horizontal second portion 110b corresponds to and is defined by the top surface 109 of the flange 23 and the bottom surface 108 of the electrode 40. Breaks in the horizontal second portion 110b of the gap 110 are limited to those caused by the first channel O-ring 94 and the connectors between the electrode 40 and the flange 23. The horizontal second portion 110b of the gap 110 is contiguous with the vertical first portion 110a.

The vertical first portion 110a generally corresponds with the side 112 of the workpiece holder 22. The vertical first portion 110a spans the side 112 of the workpiece holder 22 between the flange 23 and the upper surface 24 of the workpiece holder 22. The vertical first portion 110a of the gap 110 is defined on the inner side, at least in part, by the side 112 of the workpiece holder 22. The outer side of the vertical first portion 110a is defined, at least in part, by the inner perimeter 49 of the electrode 40. The outer side of the vertical first portion 110a is further defined, at least in part, by the inner perimeter 75 of the baffle plate 70. The outer side of the vertical first portion 110a is yet further defined, at least in part, by the inner perimeter 32 of the lift plates 31 of the lift mechanism 30.

The vertical first portion 110a of the gap 110 is continuous and unbroken in the vertical direction between the flange 23 and the upper surface 24 of the workpiece holder 22. The vertical first portion 110a of the gap 110 is continuous and unbroken horizontally around the side 112 of the workpiece holder 22. Thus the vertical first portion 110a of the gap 110 is unbroken and no point of contact exists between the side 112 of the workpiece holder 22 and any other components of the base assembly 14 (besides other components of the workpiece holder assembly 20 itself).

A cooling conduit 120 is embedded in the electrode 40 and configured to pass a coolant, thereby absorbing heat from the proximate portions of the electrode 40 and other components. The positioning of the cooling conduit 120 proximate the first channel O-ring 94 and the connectors between the flange 23 and the electrode 40 further inhibits heat transfer from the workpiece holder 22.

In one embodiment, the plasma treatment system 10 is associated with an enclosure that defines a workspace for processing a plurality of workpieces 26. The workspace is held at an atmospheric pressure. A workpiece input apparatus is configured to receive the plurality of workpieces from external the enclosure, e.g., from a robot. A plasma treatment apparatus, such as the plasma treatment system 10, is positioned within the enclosure and configured to perform a plasma treatment under a vacuum condition of the plasma treatment apparatus. The pressure in the vacuum condition is less than the atmospheric pressure. A transport apparatus is configured to receive the workpiece from the workpiece input apparatus and position the workpiece at the plasma treatment apparatus for plasma treatment. Although the enclosure is at atmospheric pressure when receiving the workpiece, the size of the enclosure is small enough that the vacuum applied can quickly evacuate the enclosure thereby effectively maintaining a vacuum condition.

Numerous benefits are realized by a base assembly 14 configured according to one or more aspects of the disclosure. For example, by eliminating any direct point of contact, and thus also direct heat transfer, over the vertical first portion 110a of the gap 110 and limiting the direct points of contact over the horizontal second portion 11b of the gap 110 to their connectors and the first channel O-ring 94, superior thermal isolation of the workpiece holder assembly 20 is achieved. The configuration of the heating elements 25 and the insulator piece 104 further contribute to the thermal isolation, as well as allowing for more efficient heat transfer from the heating elements 25 to the workpiece holder 22. The thermal isolation may maintain the other components of the base assembly 14 at a temperature that is safe to the human touch. By maintaining the other components of the base assembly 14 at a safe-to-touch temperature, the need for guards or heat barriers is eliminated or reduced, worker safety is improved, and the footprint of the plasma treatment system 10 is reduced. In addition, since less heat is lost to the other components of the base assembly 14 and the heat transfer from the heating elements 25 to the workpiece holder 22 is improved, less energy is required to power the heating elements 25, thus lowering the cost of operation. The improved thermal isolation and heat transfer also afford reduced heat up times for the plasma treatment system 10.

### Liquid Cooling for Electrode

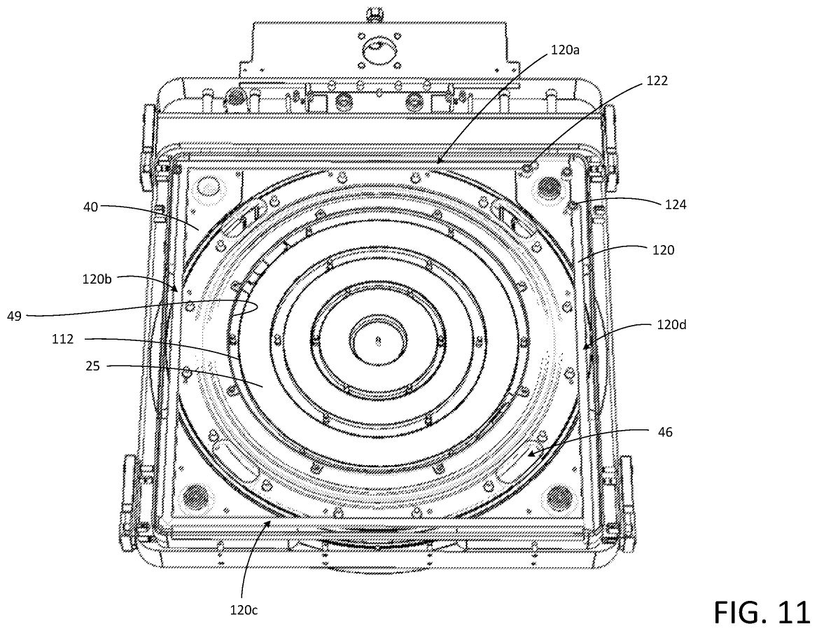

With further reference to FIGS. 9 and 10 and additional reference to FIG. 11, in which like reference numerals refer to like features in the Figures, aspects of the plasma treatment system 10 relating to electrode liquid cooling shall now be described, at least in part. Description of such aspects of the plasma treatment system 10 is not confined to this subsection. The same, additional, or alternative aspects of the plasma treatment system 10 relating to electrode liquid cooling may be found throughout the disclosure.

FIG. 11 illustrates a perspective, cross-sectional view of the base assembly 14. The base assembly 14 illustrated in FIG. 11 is horizontally (on the X-Z plane) cross-sectioned approximately at the electrode 40. Thus, FIG. 11 shows the electrode 40 configured with the passages 46 leading to the channel 58 of the chamber base 50. The sides 112 of the workpiece holder 22 and the inner perimeter 49 of the electrode 40 are further shown.

The electrode 40 is configured with the cooling conduit 120 that is embedded within the electrode 40. The cooling conduit 120 generally encircles the periphery of the electrode 40. The vertical (Y axis) position of the cooling conduit 120 in the base assembly 14 approximately corresponds to the vertical position of the horizontal second portion 110b of the gap 110. The vertical position of the cooling conduit 120 additionally approximately corresponds to the vertical position of the first channel O-ring 94. The cooling conduit is configured with a first portion 120a, a second portion 120b, a third portion 120c, and a fourth portion 120d corresponding to the four sides of the electrode 40, respectively.

The cooling conduit 120 is fed by the cooling supply 38 (FIG. 2). Water may serve as the coolant, for example, but other types of coolants also may be used. The electrode 40 is configured with a coolant inlet 122 to receive coolant from the cooling supply 38. The coolant is passed to the first portion 120a of the cooling conduit 120 via the coolant inlet 122. The coolant thereby flows through the electrode 40 within the cooling conduit 120. As the coolant flows through the cooling conduit 120, the coolant absorbs heat from the electrode 40, such as any heat that overcame the thermal isolation of the workpiece holder assembly 20. The coolant further absorbs heat caused by the plasma generation in the processing space and the electrical conduction with the electrode of the lid assembly 12. The location of the cooling conduit 120 further inhibits heat transfer near the O-ring 107, the first channel O-ring 94, and the second channel O-ring 92.

The electrode 40 is configured with a coolant outlet 124 at which coolant, having passed through the cooling conduit 120, exits the fourth portion 120d of the cooling conduit 120. The heated coolant is returned to the cooling supply 38, which may be equipped with one or more heat sinks or the like to dissipate heat from the received coolant. The cooling supply 38 may recycle the coolant back to the cooling conduit 120.

Numerous benefits are realized by the plasma treatment system 10 configured with a liquid cooled electrode 40. For example, the plasma treatment system 10 configured according to at least some aspects of the disclosure relating to liquid cooling the electrode 40 allows for the plasma treatment system 10 to be more compact than otherwise possible. In a system not so configured, a larger air space is required between a heated workpiece holder and the components of the system.

### Workpiece Cooling Monitoring

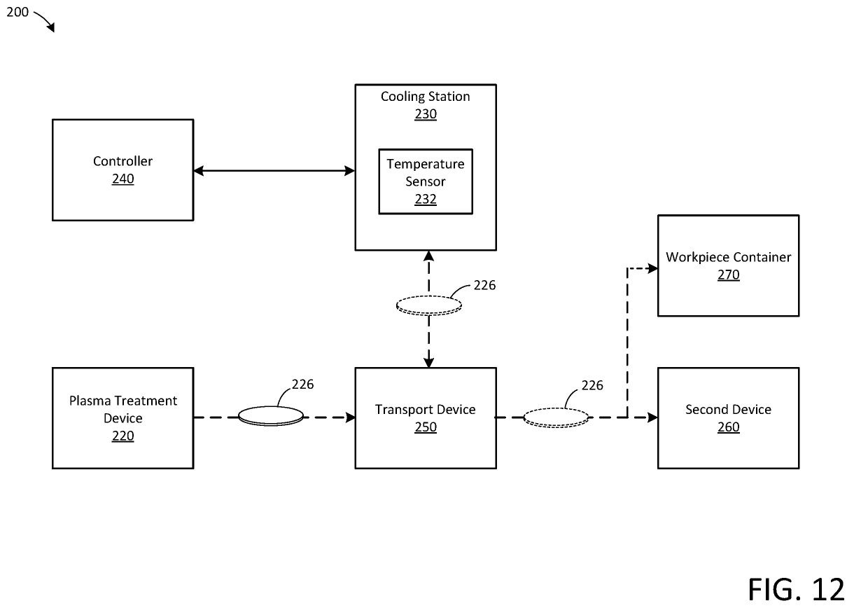

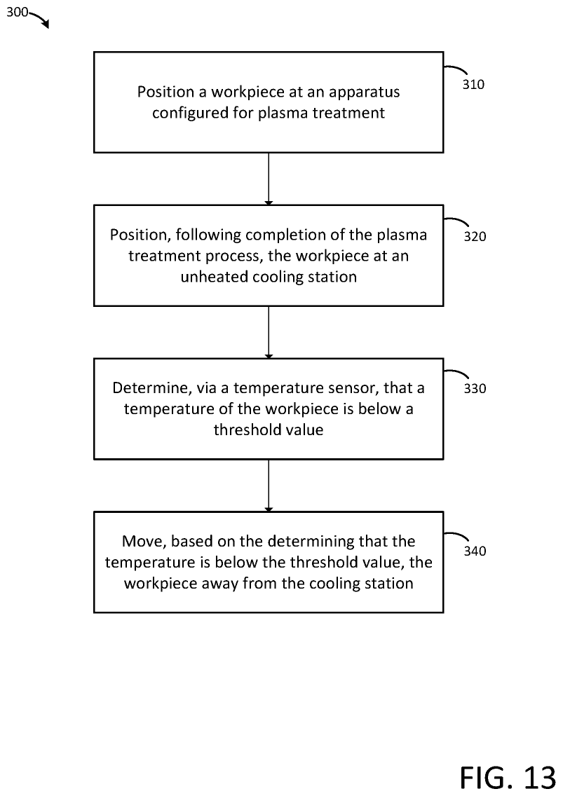

With reference to FIGS. 12 and 13, in which like reference numerals refer to like features in the Figures, aspects of a workpiece processing system 200 relating to workpiece cooling monitoring shall now be described, at least in part. Description of such aspects of the workpiece processing system 200 is not confined to this subsection. The same, additional, or alternative aspects of the workpiece processing system 200 relating to workpiece cooling monitoring may be found throughout the disclosure.

FIG. 12 illustrates the workpiece processing system 200 configured to effectuate a plasma treatment to a workpiece 226 (e.g., the workpiece 26 described in relation to FIGS. 1 through 10). The workpiece processing system 200 comprises a plasma treatment device 220 configured to perform the plasma treatment on the workpiece 226. The plasma treatment device 220 may be the same or similar as the plasma treatment system 10 described in relation to FIGS. 1 through 10.

The workpiece processing system 200 further comprises a transport device 250 configured to transport the workpiece 226 between devices, stations, workpiece storage or transport containers, or the like. The workpiece processing system 200 further comprises a cooling station 230 configured with a temperature sensor 232. The cooling station 230 may be an unheated cooling station. The cooling station 230 is configured to receive the plasma-treated workpiece 226 (shown in shadow in FIG. 11) from the transport device 250 and measure the temperature of the workpiece 226 as the workpiece 226 cools.

The cooling station 230 may be communicatively connected to a controller 240, thus the cooling station 230 may send messages to the controller regarding workpiece temperature. Although not indicated in FIG. 11 for clarity of illustration, the controller 240 may be communicatively connected with other components of the workpiece processing system 200, including the plasma treatment device 220, the transport device 250, and the second device 260.

The controller may be implemented as a general use computer, specialized hardware, other form of computing device, software, or a combination thereof. In any case, the controller is equipped with a processor and memory. The memory may store instructions that, when executed by the processor, cause the controller to effectuate operations described herein, including those relating to monitoring workpiece cooling. The controller 240 may be further equipped with one or more communication interfaces, including a computer network interface. The controller 240 may be further equipped with one or more input and/or output devices to allow human interaction with the controller 240, such a keyboard, pointing device, and a monitor.

The controller 240 may be integrated with one or more of the components of the workpiece processing system 200. For example, the controller 240 may be integrated with the cooling station 230, the plasma treatment device 220, and/or the transport device 250. Thus, the cooling station 230, the plasma treatment device 220, and/or the transport device 250 so configured may manage and direct operations of the workpiece cooling system 200 with respect to, at the least, cooling the workpiece 226.

The controller 240 is configured to receive data from the cooling station 230, including temperature data describing the temperature of the workpiece 226 and other related aspects, such as elapsed cooling time. The controller 240 processes the temperature data and determines, based on the temperature data, if the workpiece 226 is sufficiently cool and ready to proceed in the associated processing operation. For example, the controller 240 may determine that the workpiece should be transported to another device, station, container, or the like. As an example, the controller 240 may determine if the temperature of the workpiece is below a threshold temperature value. If so, the controller 240 may send a message to the cooling station 230 indicating that the cooling of the workpiece 226 should be deemed complete. Or if the controller 240 determines that the workpiece 226 is not below the threshold temperature value, the controller 240 may send a message to the cooling station 230 indicating that the workpiece 226 should be retained at the cooling station 230 for further cooling.

The workpiece processing system may further comprise a second device 260, such as a device configured to implement further processing of the workpiece. The workpiece processing system 200 comprises or is otherwise associated with a workpiece container 270, such as a Front Opening Universal (or Unified) Pod (FOUP) or Equipment Front End Module (EFEM), configured to receive the treated workpiece 226.

FIG. 13 illustrates a flow diagram 300 relating to monitoring workpiece cooling at a cooling station, such as the cooling station 230. At step 310, a workpiece (e.g., the workpiece 226) is positioned at an apparatus (e.g., the plasma treatment device 220) configured to perform a plasma treatment process. The plasma treatment process thereby may be performed on the workpiece. At step 320, following completion of the plasma treatment process, the workpiece is positioned, such as by the transport device 250, at an unheated cooling station.

At step 330, a temperature of the workpiece is determined via a temperature sensor (e.g., the temperature sensor 232) associated with the cooling station. The cooling station may comprise the temperature sensor, for example. It is determined, based on the temperature of the workpiece, that the temperature of the workpiece is below a threshold temperature value. The threshold temperature value may be the maximum temperature at which the workpiece may proceed for further processing, for example. The determination that the temperature is below the threshold temperature value may be performed by a controller (e.g., the controller 240) in communication with the cooling station. The controller may send a message to the cooling station indicating whether the temperature of the workpiece is below the threshold temperature value. The controller may additionally or alternatively send a message to the transport device indicating for the transport device to remove the workpiece from the cooling station.

At step 340, based on determining that the temperature has fallen below the threshold temperature value, the workpiece is moved away from the cooling station. The workpiece may be moved away from the cooling station by the transport device, for example. The workpiece may be then transported to a second device (e.g., the second device 260) for further processing of various sorts. Additionally or alternatively, the workpiece may be deposited in a container (e.g., the workpiece container 270) for storage or other transport.

The aspects relating to workpiece cooling monitoring described herein provide numerous benefits. For example, such aspects provide workpiece processing that is faster and results in better quality treated workpieces. For example, a cooling station using a pre-determined, fixed cooling time may allow a workpiece to sit with the cooling station for longer than needed, thereby decreasing throughput efficiency. A cooling station using a pre-determined, fixed cooling time may also signal for the workpiece to be moved from the cooling station prematurely, thereby increasing the number of plasma treated workpieces of unsatisfactory quality.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Disclosed are components that may be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that may be performed it is understood that each of these additional steps may be performed with any specific embodiment or combination of embodiments of the disclosed methods.

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

It will be apparent to those skilled in the art that various modifications and variations may be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

1.-30. (canceled)

31. An apparatus for treating a workpiece with plasma, the apparatus comprising:
a chamber partially defining a processing space for receiving process gas, wherein the chamber is under vacuum during treatment of the workpiece with plasma;
a base assembly defining a lower end of the processing space, wherein the base assembly comprises a workpiece holder having a perimeter and configured to receive the workpiece, a baffle plate having an outer perimeter, an electrode coupled to the baffle plate and having a sidewall, and a chamber base surrounding an outer surface of the sidewall of the electrode, and wherein a majority of the outer perimeter of the baffle plate is proximate to, but not in direct contact with, an inner surface of the sidewall of the electrode;
a process gas supply port in the chamber for introducing the process gas to the processing space; and
a plasma excitation source operable to provide a plasma in the processing space from the process gas for treating the workpiece;
the majority of the outer perimeter of the baffle plate and the inner surface of the sidewall of the electrode being arranged to define a gap for evacuating said processing space during treatment of the workpiece with plasma.

32. The apparatus of claim 31, wherein the base assembly defines a flow path via which said processing space is evacuated from the base assembly.

33. The apparatus of claim 32, wherein the flow path comprises a first vertical portion vertically offset from a second vertical portion.

34. The apparatus of claim 33, wherein the first vertical portion is defined by a first vertical passage and the second vertical portion is defined by a second vertical passage, the second vertical passage being vertically offset from the first vertical passage.

35. The apparatus of claim 34, wherein the plasma excitation source comprises the electrode and the electrode is positioned vertically between the chamber base and the baffle plate in the base assembly, and wherein the first vertical passage is defined by the electrode and the second vertical passage is defined by the chamber base.

36. The apparatus of claim 35, wherein the baffle plate and the electrode are coupled and define an interior space between the baffle plate and the electrode, and wherein the interior space between the baffle plate and the electrode defines a portion of the flow path immediately subsequent to evacuation of said processing space.

37. The apparatus of claim 36, wherein the portion of the flow path defined by the interior space between the baffle plate and the electrode comprises a first lateral portion prior to the first vertical passage defined by the electrode.

38. The apparatus of claim 37, wherein the electrode is coupled to the chamber base and the first vertical passage passes to the chamber base.

39. The apparatus of claim 38, wherein the chamber base defines a circular channel configured to define a second lateral portion of the flow path subsequent to the first vertical passage.

40. The apparatus of claim 39, wherein a lateral direction of the first lateral portion of the flow path and a lateral direction of the second lateral portion of the flow path are substantially opposite one another.

41. The apparatus of claim 39, wherein the second vertical passage is defined by a floor of the circular channel of the chamber base.

42. The apparatus of claim 41, wherein a vacuum plate is coupled to a bottom end of the chamber base, the coupled chamber base and the vacuum plate defining a vacuum space configured with a vacuum port connected to a vacuum source.

43. The apparatus of claim 42, wherein the vacuum space defines a third lateral portion of the flow path, wherein the third lateral portion of the flow path extends laterally from a periphery of the vacuum space and the vacuum port.

44. The apparatus of claim 35, wherein the electrode defines two or more vertical passages and the chamber base defines two or more vertical passages, the two or more vertical passages defined by the electrode being vertically offset from each of the two or more vertical passages defined by the chamber base.

45. The apparatus of claim 44, wherein the two or more vertical passages defined by the electrode comprises four vertical passages and the two or more vertical passages defined by the chamber base comprises four vertical passages, the four vertical passages defined by the electrode being vertically offset from each of the four vertical passages defined by the chamber base by at least 30 degrees relative to a center of at least one of the electrode and the chamber base.

46. The apparatus of claim 45, wherein the four vertical passages defined by the electrode are vertically offset from each of the four vertical passages defined by the chamber base by 45 degrees relative to the center of the at least one of the electrode and the chamber base.

47. The apparatus of claim 32, wherein a first portion of the flow path is defined by the gap and a second portion of the flow path comprises a horizontal portion immediately subsequent to the first portion of the flow path.

48. The apparatus of claim 47, wherein the horizontal portion of the flow path is defined between at least a portion of the baffle plate and at least a portion of the electrode.

49. The apparatus of claim 47, wherein a third, vertical portion of the flow path is defined by a vacuum conduit leading from a vacuum space in the base assembly.

50. The apparatus of claim 31, wherein an entirety of the outer perimeter of the baffle plate is proximate to, but not in direct contact with, the inner surface of the sidewall of the electrode.
